(19) United States
(12) Patent Application Publication
(10) Pub. No.: US 2009/0183985 A1
(43) Pub. Date: Jul. 23, 2009

(54) METHOD OF MANUFACTURING MAGNETIC RECORDING MEDIUM

(75) Inventors: Yuki YOSHIDA, Kawasaki (JP); Hideaki TAKAHOSHI, Higashine (JP); Shinya SATO, Higashine (JP); Isatake KAITSU, Higashine (JP); Akira KIKUCHI, Higashine (JP); Jun TAGUCHI, Kawasaki (JP); Ryo KURITA, Kawasaki (JP)

Correspondence Address: Fujitsu Patent Center;C/O CPA Global, P.O. Box 52050, Minneapolis, MN, 55402, US

(73) Assignee: FUJITSU LIMITED, Kawasaki (JP)

(21) Appl. No.: 12/355,279

(22) Filed: Jan. 16, 2009

(30) Foreign Application Priority Data
Jan. 18, 2008 (JP) 2008-008936

(51) Int. Cl. C23C 14/34

(52) U.S. Cl. 204/192.15

(57) ABSTRACT

One aspect of the embodiments utilizes, according to an aspect of the invention, a method of manufacturing a magnetic recording medium, which includes an intermediate layer and a granular magnetic layer as a recording layer sequentially formed on a non-magnetic substrate, includes the steps of forming the intermediate layer and forming the granular magnetic layer. The granular magnetic layer includes a plurality of magnetic particles made of a Co alloy and an oxide magnetically separating the plurality of magnetic particles by a sputtering method using a target. The target includes a Co alloy, one or more first oxides selected from a group of oxides of Si, Ti, Ta, Cr, W, and Nb, and a second oxide composed of a Co oxide.

### CROSS-REFERENCE TO RELATED APPLICATIONS

This application is based upon and claims the benefit of priority of prior Japanese Patent Application No. 2008-8936, filed on Jan. 18, 2008, the entire contents of which are incorporated herein by reference.

### BACKGROUND

1. Field

The embodiment(s) discussed herein is (are) related to a method of manufacturing a magnetic recording medium suitable for high-density recording.

2. Background

For example, magnetic storage apparatuses such as magnetic disk apparatuses use a read head using a tunnel magneto-resistance element and a magnetic recording medium of a perpendicular magnetic recording type to improve recording density. In order to further improve the recording density of the magnetic recording medium, it is necessary to further reduce medium noise. In order to reduce the medium noise, it is necessary to microcrystallize a recording layer forming the magnetic recording medium and/or to magnetically separate the crystal particles of the recording layer.

In recent years, a perpendicular magnetic recording medium has been proposed in which a recording layer is formed by a sputtering method using a target made of a non-magnetic material or a target including a non-magnetic material, in order to reduce the medium noise. These targets are used to form a recording layer having a granular structure in which a non-magnetic material is formed at a particle interface between magnetic particles to magnetically separate the magnetic particles, thereby reducing the medium noise.

In the recording layer having the granular structure, the magnetic interaction between the magnetic particles is reduced by the non-magnetic material. A metal oxide has generally been used as the non-magnetic material. When a stable oxide is used as the metal oxide, the oxide can reliably segregate the magnetic particles. It is effective to use any of the oxides of, for example, Ti, Si, Cr, Ta, W, and/or Nb to reliably achieve the magnetic separation between the magnetic particles.

However, when the recording layer having the granular structure using the metal oxide is formed by sputtering, the metal oxide is typically decomposed into metal and oxygen at a certain ratios. The decomposed metal is incorporated into the magnetic particles of an alloy, which results in the deterioration of magnetic characteristics. That is, even if the amount of metal oxide is increased to further reduce the magnetic interaction between the magnetic particles, the excessive increase of metal oxide makes magnetic characteristics of the magnetic particles deteriorate. That is, the effect of further reducing the magnetic interaction between the magnetic particles is not obtained, but the medium noise is increased. As described above, it is difficult to increase the amount of metal oxide to further reduce the medium noise.

For example, when about 8 mol. % to about 12 mol. % of SiO₂ is added, the coercivity Hc of the recording layer is lowered, and the magnetic interaction between the magnetic particles is not reduced, which is disclosed in Y. Inaba et al., “Optimization Of the SiO₂ Content in CoPtCr—SiO₂ Perpendicular Recording Media for High-Density Recording”, IEEE TRANSACTIONS ON MAGNETICS, VOL. 40, No. 4, pp. 2486-2468, JULY 2004. Actually, it has been found that, when the recording layer having the granular structure is formed of 8 mol. % or more of SiO₂ or TiO₂, the magnetic characteristics deteriorate. Next, the notation of the composition of a magnetic material forming the recording layer having the granular structure will be described. For example, it is considered that an alloy portion is made of Co, Cr, and Pt and a non-magnetic material separating the magnetic particles is SiO₂. It is assumed that a material includes atoms at the following ratio: the number of Co atoms is a; the number of Cr atoms is b; the number of Pt atoms is c; the number of Si atoms is d; and the number of O atoms is d×2. In this case, the compositions of the Co, Cr, and Pt atoms are represented by a/(a+b+c+d) at. %, b/(a+b+c+d) at. %, and c/(a+b+c+d) at. %, respectively, and the composition of SiO₂ is represented by d/(a+b+c+d)×100 mol. %. When the oxide of the same element as that in an alloy portion is included in the non-magnetic material, metal atoms of the alloy and atoms of the oxide are separately calculated.

A perpendicular magnetic recording medium including a recording layer formed of a CoPt alloy including an oxide is disclosed in, for example, Japanese Laid-Open Patent Publication No. 2004-310910. In addition, for example, Japanese Laid-Open Patent Publication No. 2007-164826 discloses a horizontal (or longitudinal) magnetic recording medium including a recording layer having a granular structure in which CoPt ferromagnetic particles are separated by an oxide.

In the related art, the amount of oxide is increased to reduce the magnetic interaction between the magnetic particles of the recording layer, thereby reducing medium noise. However, an excessive increase of oxide deteriorates the magnetic characteristics of the magnetic particles, which makes it difficult to further reduce the medium noise. One of the causes of the deterioration of the magnetic characteristics is that, when the recording layer is formed by sputtering, an oxide is decomposed into metal and oxygen and the metal is inserted between the magnetic particles.

### SUMMARY

According to an aspect of the invention, a method of manufacturing a magnetic recording medium including an intermediate layer and a granular magnetic layer as a recording layer, sequentially formed on a non-magnetic substrate, includes the steps of forming the intermediate layer and forming the granular magnetic layer. The granular magnetic layer includes a plurality of magnetic particles made of a Co alloy and an oxide magnetically separating the plurality of magnetic particles by a sputtering method using a target. The target includes a Co alloy, one or more first oxides selected from a group of oxides of Si, Ti, Ta, Cr, W, and Nb, and a second oxide composed of a Co oxide.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 illustrates a cross-sectional view illustrating a magnetic recording medium manufactured according to the first embodiment of the present invention;

FIG. 2 illustrates a diagram illustrating the coercivity of an oxide granular magnetic layer according to Comparative example 1;

FIG. 3 illustrates a diagram illustrating the coercivity of the oxide granular magnetic layer when 8 mol. % of TiO₂ is added to the oxide granular magnetic layer and 10 mol. % of TiO₂ is added to the oxide granular magnetic layer in the first embodiment;

FIG. 4 illustrates a diagram illustrating a variation in a coercivity Hc with respect to the amount of CoO added to an oxide granular magnetic layer according to the second embodiment of the present invention;

FIG. 5 illustrates a diagram illustrating a variation in the measured value of saturated magnetization with respect to the amount of CoO added to the oxide granular magnetic layer;

FIG. 6 illustrates a cross-sectional view illustrating a magnetic recording medium manufactured according to the third embodiment of the present invention; and

FIG. 7 illustrates a diagram illustrating a variation in a VMM value with respect to the amount of CoO added to the oxide granular magnetic layer (first magnetic layer).

### DESCRIPTION OF EMBODIMENT(S)

According to an embodiment of the present invention, a magnetic recording medium has a structure in which a recording layer including a plurality of magnetic particles of a Co alloy and an oxide that magnetically separates the plurality of magnetic particles is formed on a non-magnetic substrate. The recording layer includes a Co alloy and a plurality of oxides including one or more oxides (first oxide) selected from the group consisting of oxides of Si, Ti, Ta, Cr, W, and Nb, and a Co oxide (second oxide). The first oxide has an oxide generation energy that is lower than that of the Co oxide (second oxide). For example, the first oxide may be TiO₂. A sputtering target used for sputtering includes about 6 mol. % or more of TiO₂. The sputtering target used for sputtering includes about 1 mol. % to about 6 mol. % of Co oxide (second oxide). The sputtering target used to form the recording layer may be a single target including the Co alloy and the first and second oxides, or two or more targets including at least one of the Co alloy and the first and second oxides.

A metal oxide for separating the magnetic particles is sputtered to be decomposed into metal and oxide. However oxygen generated by the decomposition of the Co oxide and metal generated by the decomposition of a metal oxide is coupled to be metal oxide again by sputtering the Co oxide and the metal oxide. The metal oxide stably separates the magnetic particles. Therefore, it is possible to reliably reduce the magnetic interaction between the magnetic particles without deteriorating magnetic characteristics of the magnetic particles. In this way, it is possible to reduce medium noise, improve read/write characteristics (R/W characteristics), and increase the recording density of a magnetic recording medium. For example, the R/W characteristics are an index indicating the performance of a magnetic recording medium on the basis of the error rate of read data when certain data is written to the magnetic recording medium a given number of times and then the data is read. The error rate is defined as, for example, the total number of sectors from which data is read.

It does not matter when Co atoms decomposed from the Co oxide are infiltrated into a Co alloy portion of the recording layer. However, the oxide generation energy of the Co oxide per mole of oxygen is considerably higher than that of the oxide of Si, Ti, Ta, Cr, W, or Nb per mole of oxygen. Therefore, if there are any one of Co atoms, O (oxygen) atoms and Si, Ti, Ta, Cr, W, and Nb atoms decomposed by sputtering, the Si, Ti, Ta, Cr, W, and Nb atoms are coupled to oxygen more preferentially than the Co atoms to stably generate an oxide.

Next, embodiments of a method of manufacturing a magnetic recording medium according to the present invention will be described with reference to the accompanying drawings.

### The First Embodiment

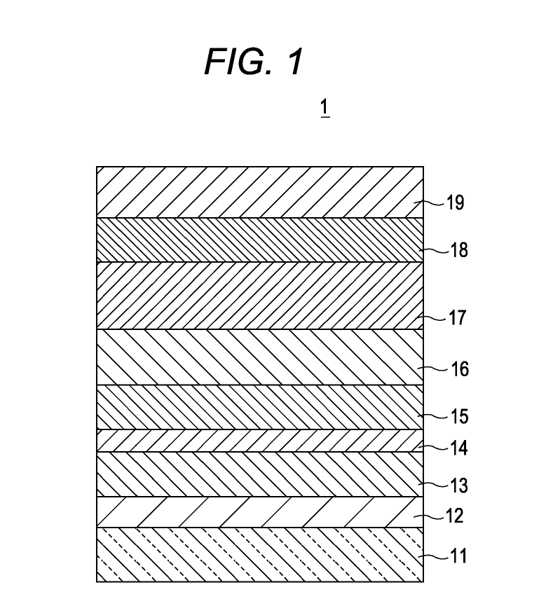

FIG. 1 is a cross-sectional view illustrating a magnetic recording medium manufactured according to the first embodiment of the present invention. In this embodiment, the present invention is applied to a perpendicular magnetic recording medium. As shown in FIG. 1, a CrTi adhesive layer 12, a CoFeZrTa soft magnetic layer 13, a Ru coupling layer 14, a CoFeZrTa soft magnetic layer 15, a NiW seed layer 16, a Ru intermediate layer 17, a non-magnetic CoCr—SiO₂ granular intermediate layer 18, and a (Co₇₄Cr₉Pt₁₇)₉₆₋ₓ—(TiO₂)ₓ—(CoO)₄ oxide granular magnetic layer 19 were formed on a non-magnetic substrate 11. A perpendicular magnetic recording medium 1 was manufactured by changing the amount of TiO₂ added to the oxide granular magnetic layer 19. Specifically, the amount of TiO₂ added to a sputtering target used to form the oxide granular magnetic layer 19 by sputtering was changed. When a single sputtering target is used to form the oxide granular magnetic layer 19, the content of Co in the oxide granular magnetic layer 19 (or the sputtering target) is 74×(96−x)/100 at. %. The contents of Cr and Pt are represented by the same expression as described above. That is, the content of Cr in the oxide granular magnetic layer 19 (or the sputtering target) is 9×(96−x)/100 at. %, and the content of Pt in the oxide granular magnetic layer 19 is 17×(96−x)/100 at. %. In addition, the content of TiO₂ in the oxide granular magnetic layer 19 (or the sputtering target) is x mol. %, and the content of CoO is 4 mol. %.

The non-magnetic substrate 11 may be, for example, a glass substrate, a NiP-plated Al substrate, a plastic substrate, or a Si substrate. For convenience of description, characteristics of the layers are described assuming that the CrTi adhesive layer 12 has a thickness of 5 nm, the CoFeZrTa soft magnetic layer 13 has a thickness of 25 nm, the Ru coupling layer 14 has a thickness of 0.5 nm, the CoFeZrTa soft magnetic layer 15 has a thickness of 25 nm, the NiW seed layer 16 has a thickness of 8 nm, the Ru intermediate layer 17 has a thickness of 20 nm, the non-magnetic CoCr—SiO₂ granular intermediate layer 18 has a thickness of 3 nm, and the (Co₇₄Cr₉Pt₁₇)₉₆₋ₓ—(TiO₂)ₓ—(CoO)₄ oxide granular magnetic layer 19 has a thickness of 8 nm. However, the experimental results of the inventors proved that substantially the same characteristics as described above were obtained even when the CrTi adhesive layer 12 had a thickness in the range of 1 nm to 30 nm, the CoFeZrTa soft magnetic layer 13 had a thickness in the range of 10 nm to 50 nm, the Ru coupling layer 14 had a thickness in the range of 0.3 nm to 2.0 nm, the CoFeZrTa soft magnetic layer 15 had a thickness in the range of 10 nm to 50 nm, the NiW seed layer 16 had a thickness in the range of 2 nm to 20 nm, the Ru intermediate layer 17 had a thickness in the range of 5 nm to 30 nm, the non-magnetic CoCr—SiO₂ granular intermediate layer 18 had a thickness in the range of 1 nm to 10 nm, the (Co₇₄Cr₉Pt₁₇)₉₆₋ₓ—(TiO₂)ₓ—(CoO)₄ oxide granular magnetic layer 19 had a thickness in the range of 5 nm to 30 nm.

In the following description, for convenience, as deposition conditions, the layers 12 to 19 are formed by a DC magnetron sputtering method using an Ar gas as a sputtering gas. The layers 12 to 16 are formed at a pressure of 0.67 Pa, the Ru intermediate layer 17 is formed at a pressure of 5 Pa, the non-magnetic CoCr—SiO₂ granular intermediate layer 18 is formed at a pressure of 3 Pa, and the (Co₇₄Cr₉Pt₁₇)₉₆₋ₓ—(TiO₂)ₓ—(CoO)₄ oxide granular magnetic layer 19 is formed at a pressure of 4 Pa. However, the experimental results of the inventors proved that substantially the same characteristics as described above were obtained even when the layers 12 to 16 were formed at a pressure in the range of 0.1 Pa to 2.0 Pa, and the layers 17 to 19 were formed at a pressure in the range of 0.5 Pa to 15 Pa.

However, the sputtering method is not limited to the DC magnetron sputtering method, and a DC sputtering method or an RF sputtering method may be used. The sputtering gas is not limited to the Ar gas, and, for example, Xe gas, Kr gas, or Ne gas may be used.

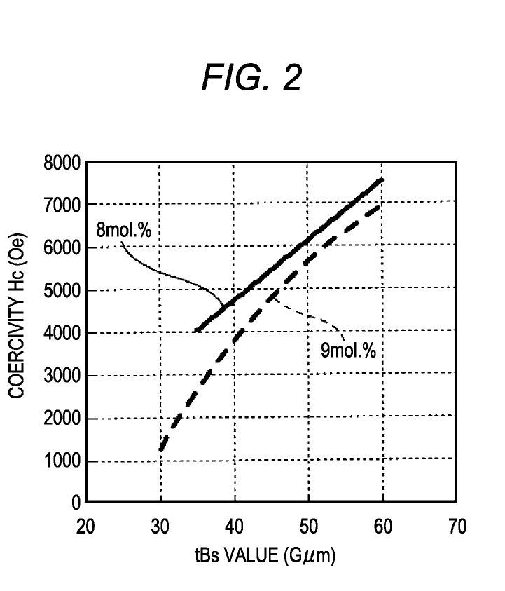

In Comparative example 1, a perpendicular magnetic recording medium was manufactured under the same deposition conditions as those in the first embodiment except that (Co₇₄Cr₉Pt₁₇)₁₀₀₋ₓ—(TiO₂)ₓ with no CoO was used as the oxide granular magnetic layer (corresponding to the oxide granular magnetic layer 19). FIG. 2 is a diagram illustrating the coercivity Hc of an oxide granular magnetic layer according to Comparative Example 1. In FIG. 2, the vertical axis indicates the coercivity Hc (Oe) of the oxide granular magnetic layer, and the horizontal axis indicates a tBs value (Gμm). The tBs value is the product of the thickness t (μm) of the oxide granular magnetic layer and the saturation magnetic flux density Bs (G) of the oxide granular magnetic layer. The highest coercivity Hc is obtained when 8 mol. % of TiO₂ is added to the oxide granular magnetic layer. In FIG. 2, a solid line indicates when 8 mol. % of TiO₂ is added, and a dashed line indicates when 9 mol. % of TiO₂ is added. As can be seen from FIG. 2, when 8 mol. % or more of TiO₂ is added, the coercivity Hc is reduced.

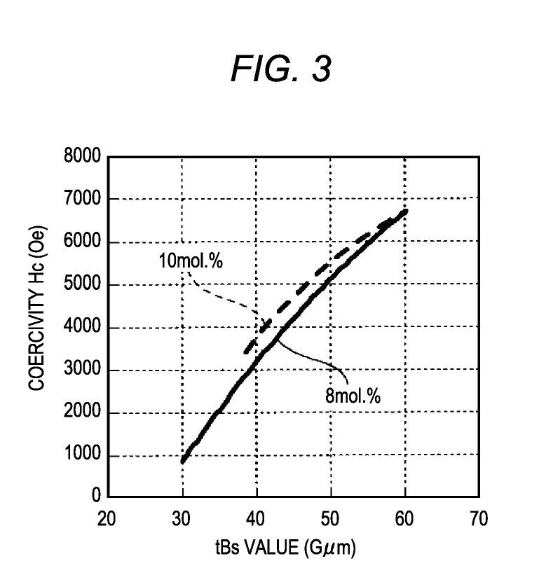

In this embodiment, the addition of an excessively large amount of TiO₂ to the oxide granular magnetic layer 19 is one of the causes that does not obtain desired effects. When TiO₂ is decomposed into Ti and O and Ti is infiltrated into the magnetic particles, oxygen deficiency occurs. In order to prevent the oxygen deficiency, CoO is added to the oxide granular magnetic layer 19. FIG. 3 is a diagram illustrating the coercivity Hc of the oxide granular magnetic layer 19 when 8 mol. % of TiO₂ is added to the oxide granular magnetic layer 19 and 10 mol. % of TiO₂ is added to the oxide granular magnetic layer 19. In FIG. 3, the vertical axis indicates the coercivity Hc (Oe) of the oxide granular magnetic layer 19, and the horizontal axis indicates a tBs value (Gμm). The tBs value is the product of the thickness t (μm) of the oxide granular magnetic layer 19 and the saturation magnetic flux density Bs (G) of the oxide granular magnetic layer 19. When CoO is added to the oxide granular magnetic layer 19, the coercivity Hc of the oxide granular magnetic layer 19 is not reduced even when the amount of TiO₂ added to the oxide granular magnetic layer 19 is increased from 8 mol. % to 10 mol. %. On the contrary, the coercivity Hc is increased due to a reduction in the magnetic interaction between the magnetic particles. That is, when CoO is added to the oxide granular magnetic layer 19, Ti decomposed from TiO₂ is coupled to O (oxygen) atoms decomposed from CoO to generate TiO₂. Therefore, a reduction in the coercivity Hc due to the infiltration of Ti into a Co alloy portion is prevented. However, it is considered that TiO₂ is decomposed at a certain ratio. It has been found that it is difficult to obtain good results when 8 mol. % or more of TiO₂ is added to the oxide granular magnetic layer 19. However, even though the amount of TiO₂ added is less than 8 mol. %, TiO₂ is decomposed. Therefore, it is possible to consider that the effect of the addition of CoO is obtained even when the amount of TiO₂ added is less than 8 mol. %. The experimental results of the inventors proved that the coercivity Hc of the oxide granular magnetic layer 19 was increased when the amount of TiO₂ added to the oxide granular magnetic layer 19 was preferably in the range of about 6 mol. % to about 20 mol. %, more preferably, about 6 mol. % to about 12 mol. %.

A sputtering target used to form the oxide granular magnetic layer 19 may be a single target including a Co alloy such as CoCrPt, one or more oxides (first oxide) selected from the group of oxides of Si, Ti, Ta, Cr, W, and Nb, such as TiO₂, and a Co oxide (second oxide) such as CoO, or two or more targets including at least one of the Co alloy and the first and second oxides. An oxide having an oxide generation energy that is lower than that of the second oxide is used as the first oxide.

### The Second Embodiment

In the second embodiment according to the present invention, a perpendicular magnetic recording medium 1 having the same structure as that in the first embodiment was manufactured under the same deposition conditions as those in the first embodiment except that the amount of CoO added to the oxide granular magnetic layer 19 was changed.

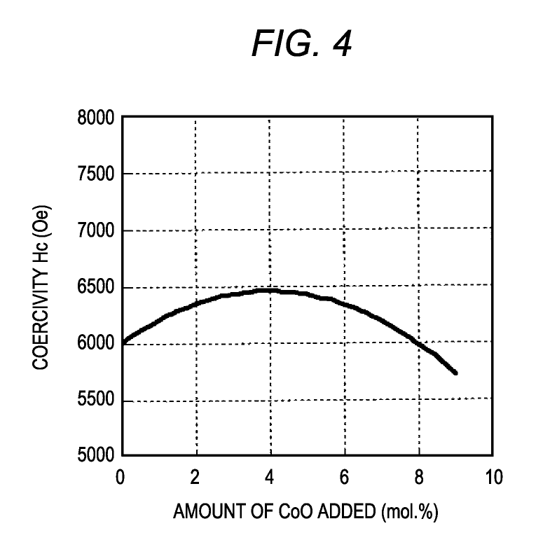

FIG. 4 is a diagram illustrating a variation in the coercivity Hc with respect to the amount of CoO added to the oxide granular magnetic layer 19 in the second embodiment. In FIG. 4, the vertical axis indicates the coercivity Hc (Oe) of the oxide granular magnetic layer 19, and the horizontal axis indicates the amount (mol. %) of CoO added to the oxide granular magnetic layer 19. As can be seen from FIG. 4, the coercivity Hc is increased when the amount of CoO added to the oxide granular magnetic layer 19 is in the range of about 1 mol. % to about 8 mol. %. This is considered to be because some of the oxygen atoms of CoO added to the oxide granular magnetic layer 19 are coupled to Ti decomposed from TiO₂ to prevent Ti from infiltrating into a Co alloy and the magnetic interaction between the magnetic particles is reduced due to the segregation of CoO.

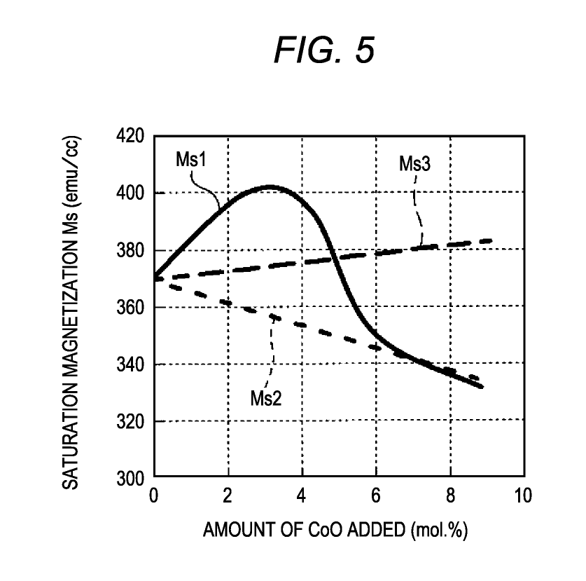

The inventors measured the saturated magnetization Ms of the oxide granular magnetic layer 19 with respect to the amount of CoO added. FIG. 5 is a diagram illustrating a variation in the measured value Ms₁ of the saturated magnetization Ms with respect to the amount of CoO added to the oxide granular magnetic layer 19. In FIG. 5, the vertical axis indicates the saturated magnetization Ms (emu/cc) of the oxide granular magnetic layer 19, and the horizontal axis indicates the amount (mol. %) of CoO added to the oxide granular magnetic layer 19. As can be seen from FIG. 5, when the amount of CoO added to the oxide granular magnetic layer 19 is in the range of about 1 mol. % to about 5 mol. %, the saturated magnetization Ms is increased. On the other hand, when the amount of CoO added to the oxide granular magnetic layer 19 is more than or equal to 6 mol. %, the saturated magnetization Ms is decreased. If CoO added to the oxide granular magnetic layer 19 remains in the oxide granular magnetic layer 19 as an oxide, the amount of Co in a Co alloy portion corresponding to the added amount of CoO is reduced. Therefore, the saturated magnetization Ms is monotonically decreased like a calculated value Ms₂ represented by the short dashed line. On the other hand, when CoO added to the oxide granular magnetic layer 19 is mostly decomposed into Co and O and most of the Co atoms are incorporated into the Co alloy, the saturated magnetization Ms is increased by the total amount of the Co atoms in the oxide granular magnetic layer 19, like a calculated value Ms₃ represented by the long dashed line. The comparison between the measured value Ms and the calculated values Ms₂ and Ms₃ shows that, when the amount of CoO added to the oxide granular magnetic layer 19 is in the range of about 1 mol. % to about 6 mol. %, the saturated magnetization Ms is greater than the calculated value Ms₂. Therefore, the Co atoms decomposed from CoO are moved to the Co alloy portion. When the amount of CoO added to the oxide granular magnetic layer 19 is in the range of about 2 mol. % to about 5 mol. %, the saturated magnetization Ms is greater than the calculated value Ms₃. Therefore, the O (oxygen) atoms decomposed from CoO are coupled to Ti and the infiltration of Ti is prevented. As a result, it may be considered that the saturated magnetization Ms is further increased. In particular, when the amount of CoO added to the oxide granular magnetic layer 19 is more than or equal to 6 mol. %, the saturated magnetization Ms is substantially equal to the calculated value Ms₂. FIG. 5 shows that the effect of the addition of CoO is not effectively obtained. That is, it was found that when the amount of CoO added to the oxide granular magnetic layer 19 is in the range of about 1 mol. % to about 6 mol. %, it is possible to obtain an oxygen supply effect according to the second embodiment; and when the amount of CoO added to the oxide granular magnetic layer 19 is in the range of about 2 mol. % to about 5 mol. %, the effect is further improved.

### The Third Embodiment

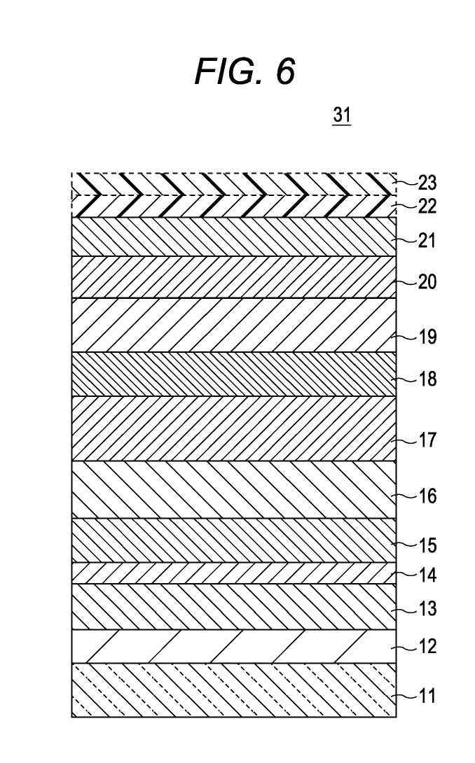

FIG. 6 is a cross-sectional view illustrating a magnetic recording medium manufactured according to Example 3 of the present invention. In the third embodiment, the present invention is applied to a perpendicular magnetic recording medium. In FIG. 6, the same components as those in FIG. 1 are denoted by the same reference numerals, and a detailed description thereof will be omitted. As shown in FIG. 6, a CrTi adhesive layer 12, a CoFeZrTa soft magnetic layer 13, a Ru coupling layer 14, a CoFeZrTa soft magnetic layer 15, a NiW seed layer 16, a Ru intermediate layer 17, a non-magnetic CoCr—SiO₂ granular intermediate layer 18, a (Co₇₄Cr₉Pt₁₇)_{92-y}—(TiO₂)₈—(CoO)_{y} oxide granular magnetic layer (first magnetic layer) 19 were formed on a non-magnetic substrate 11, and a CoCrPt—TiO₂ oxide granular magnetic layer (second magnetic layer) 20 and a CoCrPtB magnetic layer (third magnetic layer) 21 were formed thereon in order to further improve R/W characteristics. A perpendicular magnetic recording medium 31 was manufactured by changing the amount of CoO added to the oxide granular magnetic layer (first magnetic layer) 19. In order to evaluate the R/W characteristics, a DLC (diamond-like carbon) protective layer 22 and a fluorine-based lubrication layer 23 were formed on the CoCrPtB magnetic layer (third magnetic layer) 21. In the first and second embodiments, similarly, a DLC protective layer and a fluorine-based lubrication layer may be formed on the oxide granular magnetic layer 19. In the third embodiment, the first magnetic layer 19, the second magnetic layer 20, and the third magnetic layer 30 form a recording layer of the perpendicular magnetic recording medium 31.

Next, for convenience of description, characteristics in the case where the thicknesses and the deposition conditions of the layers 12 to 19 are the same as those in the first embodiment will be described. The experimental results of the inventors proved that substantially the same characteristics as described above were obtained even when the range of the thicknesses and the deposition conditions of the layers 12 to 19 were the same as those in the first embodiment. In addition, for convenience of description, characteristics in the case where the CoCrPt—TiO₂ oxide granular magnetic layer (second magnetic layer) 20 has a thickness of 5 nm and the CoCrPtB magnetic layer (third magnetic layer) 21 has a thickness of 5 nm will be described. However, the experimental results of the inventors proved that substantially the same characteristics as described above were obtained even when the CoCrPt—TiO₂ oxide granular magnetic layer (second magnetic layer) 20 had a thickness in the range of 1 nm to 20 nm and the CoCrPtB magnetic layer (third magnetic layer) 21 had a thickness in the range of 3 nm to 20 nm.

In the following description, as deposition conditions, the layers 20 and 21 are formed by a DC magnetron sputtering method using an Ar gas as a sputtering gas. In addition, the case in which the CoCrPt—TiO₂ oxide granular magnetic layer (second magnetic layer) 20 is formed at a pressure of 4 Pa and the CoCrPtB magnetic layer (third magnetic layer) 21 is formed at a pressure of 0.67 Pa will be described below. However, the experimental results of the inventors proved that substantially the same characteristics as described above were obtained even when the CoCrPt—TiO₂ oxide granular magnetic layer (second magnetic layer) 20 was formed at a pressure in the range of 0.5 Pa to 15 Pa and the CoCrPtB magnetic layer (third magnetic layer) 21 was formed at a pressure in the range of 0.1 Pa to 2 Pa.

However, the sputtering method is not limited to the DC magnetron sputtering method, and a DC sputtering method or an RF sputtering method may be used. The sputtering gas is not limited to the Ar gas, and, for example, Xe gas, Kr gas, or Ne gas may be used.

The DLC protective layer 22 was formed with a thickness of 3.5 nm by plasma CVD (chemical vapor deposition), and the fluorine-based lubrication layer 23 was formed with a thickness of 0.9 nm by dip coating. However, the forming methods of the layers 22 and 23 and the thicknesses thereof are not limited thereto.

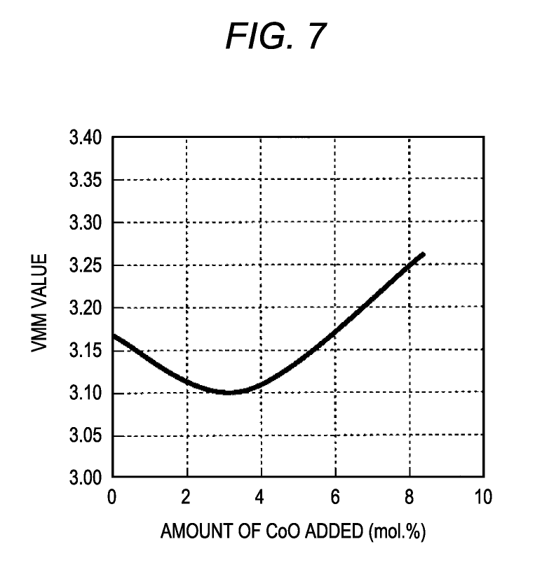

FIG. 7 is a diagram illustrating a variation in a VMM (Viterbi metric margin) value with respect to the amount of CoO added to the oxide granular magnetic layer (first magnetic layer) 19. In FIG. 7, the vertical axis indicates the VMM value, and the horizontal axis indicates the amount (mol. %) of CoO added to the oxide granular magnetic layer (first magnetic layer) 19. The VMM value indicates the error rate of the signal whose error is corrected by Viterbi decoding. As the VMM value is decreased in proportion to the error rate, the R/W characteristics of the perpendicular magnetic recording medium 31 are improved. During signal decoding, in order to clearly discriminate a correct pulse from an error pulse, it is necessary that a difference (metric value) between an ideal value and the measured value be large. The VMM value is defined as a value when a difference between the metric values by the correct pulse and the error pulse is smaller than a given threshold value. The larger the VMM value becomes, the more likely the error is to occur. As can be seen from FIG. 7, the VMM value is decreased by the addition of CoO to the oxide granular magnetic layer (first magnetic layer) 19. However, if the amount of CoO added to the oxide granular magnetic layer (first magnetic layer) 19 is more than or equal to about 6 mol. %, the VMM value increases. It is considered that the deterioration of the VMM value is caused since an excessively large amount of CoO, which is an oxygen source, is added. That is, it is preferable that the amount of CoO added to the oxide granular magnetic layer (first magnetic layer) 19 be in the range of about 2 mol. % to about 5 mol. % in order to obtain good R/W characteristics.

The effect of improving the magnetic separation between the magnetic particles by an oxide is obtained by the oxide granular magnetic layer forming the recording layer. That is, a granular magnetic layer having an oxide that magnetically separates the magnetic particles can obtain the above-mentioned effect even when it forms a recording layer having, for example, a multi-layer structure. In the third embodiment, the present invention is applied to the oxide granular magnetic layer (first magnetic layer) 19. However, the experimental results of the inventors proved that, even when the present invention was applied to the oxide granular magnetic layer (second magnetic layer) 20, the effect of improving the magnetic separation of the magnetic particles was obtained, similarly to the case in which the present invention was applied to the oxide granular magnetic layer (first magnetic layer) 19. When the magnetic separation of the magnetic particles in the oxide granular magnetic layer is improved, the magnetic separation of the magnetic particles is succeeded by another magnetic layer formed on the oxide granular magnetic layer. Therefore, according to the third embodiment, the same effect as described above is obtained when the present invention is applied to only the oxide granular magnetic layer (first magnetic layer) 19, when the present invention is applied to only the oxide granular magnetic layer (second magnetic layer) 20, and when the invention is applied to both the oxide granular magnetic layers (first and second magnetic layers) 19 and 20.

In the third embodiment, the magnetic layer (third magnetic layer) 21 is not a granular type using an oxide in order to further improve the R/W characteristics.

In the first, second, and third embodiments, the sputtering target used to form the oxide granular magnetic layer 19 includes CoCrPt, the first oxide composed of TiO₂, and the second oxide composed of CoO. However, even when any of the oxides of W and Nb other than TiO₂ is used as the first oxide, the oxide is unevenly distributed between the magnetic particles to magnetically separate the magnetic particles, which can be inferred from, for example, T. P. Nolan et al., “Microstructure and Exchange Coupling of Segregated Oxide Perpendicular Recording Media”, IEEE TRANSACTIONS ON MAGNETICS, VOL. 43, NO. 2, pp. 639-644, FEBRUARY 2007, and Japanese Laid-Open Patent Publication No. 2007-52900. The experimental results of the inventors proved that, even when any of the oxides of Si, Ta, and Cr was used as the first oxide, the oxide was unevenly distributed between the magnetic particles to magnetically separate the magnetic particles. During sputtering, the atoms of a sputtering gas with high energy collide with a raw material target, and the raw material emitted from the target collides with a substrate. Therefore, when an oxide is used, a portion of the oxide is certainly segregated from oxygen. The oxides (first oxide) of Si, Ti, Ta, Cr, W, and Nb have an oxide generation energy that is lower than that of the Co oxide (second oxide). When Co is segregated from O (oxygen) for the same reason as when TiO₂ is used as the first oxide and CoO is used as the second oxide, atoms other than Co are recombined with O (oxygen) with high probability to form an oxide. Therefore, when the oxide granular magnetic layer 19 (and/or 20) and the sputtering target used to form the oxide granular magnetic layer 19 (and/or 20) include a Co alloy such as CoCrPt, one or more oxides (first oxide) selected from the group of the oxides of Si, Ti, Ta, Cr, W, and Nb, such as TiO₂, and a Co oxide (second oxide) such as CoO, it is possible to improve the magnetic separation of the magnetic particles in the oxide granular magnetic layer 19 (and/or 20).

The Co alloy forming the granular magnetic layer 19 and/or 20 is not limited to CoCrPt. For example, CoCr, CoCrTa, or CoCrPt-M may be used, where M=B, Cu, Mo, Nb, Ta, W, and/or alloys thereof may be used.

In the first, second, and third embodiments, the present invention is applicable to the perpendicular magnetic recording medium. However, the embodiments may also be required to improve the magnetic separation of the magnetic particles in the magnetic layer in a horizontal (or longitudinal) magnetic recording medium of a horizontal magnetic recording type as well as the perpendicular magnetic recording medium. Therefore, embodiments of the present invention may be applied to the horizontal magnetic recording medium as well as the perpendicular magnetic recording medium.

Although the embodiments of the present invention have been described above, the present invention is not limited to the embodiments. Various modifications and changes of the present invention can be made without departing from the scope and spirit of the invention.

According to the present invention, it is possible to achieve a method of manufacturing a magnetic recording medium capable of reducing medium noise.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A method of manufacturing a magnetic recording medium including an intermediate layer and a granular magnetic layer as a recording layer, formed on a non-magnetic substrate, the method comprising the steps of:
forming the intermediate layer; and
forming the granular magnetic layer including a plurality of magnetic particles made of a Co alloy and an oxide magnetically separating the plurality of magnetic particles by a sputtering method using a target,
wherein the target includes a Co alloy, one or more first oxides selected from a group of oxides including Si, Ti, Ta, Cr, W, and Nb, and a second oxide composed of a Co oxide.

2. The method of manufacturing a magnetic recording medium according to claim 1,
wherein the first oxide has an oxide generation energy that is lower than that of the second oxide.

3. The method of manufacturing a magnetic recording medium according to claim 1,
wherein the first oxide is TiO₂, and the amount of TiO₂ included in the target is about 6 mol. % or more.

4. The method of manufacturing a magnetic recording medium according to claim 2,
wherein the first oxide is TiO₂, and the amount of TiO₂ included in the target is about 6 mol. % or more.

5. The method of manufacturing a magnetic recording medium according to claim 1,
wherein the second oxide is CoO, and the amount of CoO included in the target is in the range of about 1 mol. % to about 6 mol. %.

6. The method of manufacturing a magnetic recording medium according to claim 2,
wherein the second oxide is CoO, and the amount of CoO included in the target is in the range of about 1 mol. % to about 6 mol. %.

7. The method of manufacturing a magnetic recording medium according to claim 1,
wherein the second oxide is CoO, and the amount of CoO included in the target is in the range of about 2 mol. % to about 5 mol. %.

8. The method of manufacturing a magnetic recording medium according to claim 2,
wherein the second oxide is CoO, and the amount of CoO included in the target is in the range of about 2 mol. % to about 5 mol. %.

9. The method of manufacturing a magnetic recording medium according to claim 1,
wherein the target is a single target including the Co alloy and the first and second oxides.

10. The method of manufacturing a magnetic recording medium according to claim 2,
wherein the target is a single target including the Co alloy and the first and second oxides.

11. The method of manufacturing a magnetic recording medium according to claim 1,
wherein the target is two or more targets including at least one of the Co alloy and the first and second oxides.

12. The method of manufacturing a magnetic recording medium according to claim 2,
wherein the target is two or more targets including at least one of the Co alloy and the first and second oxides.

13. The method of manufacturing a magnetic recording medium according to claim 1,
wherein the granular magnetic layer forms a recording layer having a single-layer structure.

14. The method of manufacturing a magnetic recording medium according to claim 2,
wherein the granular magnetic layer forms a recording layer having a single-layer structure.

15. The method of manufacturing a magnetic recording medium according to claim 1,
wherein one or more granular magnetic layers are included in a recording layer having a multi-layer structure.

16. The method of manufacturing a magnetic recording medium according to claim 2,
wherein one or more granular magnetic layers are included in a recording layer having a multi-layer structure.

17. The method of manufacturing a magnetic recording medium according to claim 1,
wherein the intermediate layer includes a Ru intermediate layer and a non-magnetic CoCr—SiO₂ granular intermediate layer, and
the magnetic recording medium is of a perpendicular magnetic recording type.

18. The method of manufacturing a magnetic recording medium according to claim 2,
wherein the intermediate layer includes a Ru intermediate layer and a non-magnetic CoCr—SiO₂ granular intermediate layer, and
the magnetic recording medium is of a perpendicular magnetic recording type.
